(19) United States
(12) Patent Application Publication
(10) Pub. No.: US 2014/0184062 A1
(43) Pub. Date: Jul. 3, 2014

(54) SYSTEMS AND METHODS FOR A LIGHT EMITTING DIODE CHIP

(71) Applicant: GE LIGHTING SOLUTIONS, LLC, East Cleveland, OH (US)

(72) Inventor: Boris KOLODIN, Beachwood, OH (US)

(73) Assignee: GE LIGHTING SOLUTIONS, LLC, East Cleveland, OH (US)

(21) Appl. No.: 13/727,904

(22) Filed: Dec. 27, 2012

(51) Int. Cl. H05B 37/02; H01L 33/62

(52) U.S. Cl. CPC H05B 37/02; H01L 33/62
USPC 315/32; 257/81; 438/24

(57) ABSTRACT

Provided is a light emitting diode (LED) chip. The LED chip includes a substrate and a mesa structure formed from a heterostructure grown on the substrate. The mesa structure includes an LED mesa portion and a photo diode (PD) mesa portion. A channel separates the LED mesa portion from the PD mesa portion.

### TECHNICAL FIELD

The technical field relates generally to light emitting diodes and, more specifically, to light emitting diodes with a photo diode sensor.

### BACKGROUND

Some white light emitting diodes (LEDs) use optical energy feedback from photo diode (PD) sensors to perform active color control. For example, active color control stabilizes the color point of solid state lamps based on red-green-blue (RGB) LEDs or blue-shifted-YAG (BSY) plus red LED architecture.

However, such PD sensors are subject to cross-talking from neighboring LEDs. Moreover, the accuracy of PD sensors is not sufficient for some applications. The cross-talk from neighboring LEDs and inaccuracy of PD sensors make it difficult to determine the optical energy emitted a single LED.

For example, it is difficult to determine when an LED has degraded such that current flowing through the LED is creating less optical energy. Without knowing when an LED has degraded, active color control does not know how to respond to compensate for the degradation. Compensation without such knowledge can accelerate the degradation of one or more LEDs.

### SUMMARY

Where an accurate measurement of the optical energy of a primary LED is made, active color control can increase current to the primary LED or to auxiliary LEDs to compensate for degradation. The various embodiments of the present disclosure are configured to accurately monitor optical energy from one LED without interruptions by optical energy from other LEDs.

According to one exemplary embodiment, an LED chip includes a substrate and a mesa structure formed from a heterostructure grown on the substrate. The mesa structure includes an LED mesa portion and a PD mesa portion. A channel separates the LED mesa portion from the PD mesa portion.

According to another exemplary embodiment, an LED system includes a first LED device and a control unit. The LED device includes an LED chip. The LED chip includes a substrate and a mesa structure formed from a heterostructure grown on the substrate. The mesa structure includes an LED mesa portion and a PD mesa portion. A channel separates the LED mesa portion from the PD mesa portion. The control unit is configured to provide a first current through the LED mesa portion and measure a photocurrent generated by the PD mesa portion.

According to yet another embodiment, a method of forming an LED chip includes growing a heterostructure on a substrate and applying an etching process to the heterostructure to form a mesa structure. The mesa structure includes an LED mesa portion and a PD mesa portion. Applying an etching process includes forming a channel that separates the LED mesa portion from the PD mesa portion.

The foregoing has broadly outlined some of the aspects and features of the various embodiments, which should be construed to be merely illustrative of various potential applications of the disclosure. Other beneficial results can be obtained by applying the disclosed information in a different manner or by combining various aspects of the disclosed embodiments. Accordingly, other aspects and a more comprehensive understanding may be obtained by referring to the detailed description of the exemplary embodiments taken in conjunction with the accompanying drawings, in addition to the scope defined by the claims.

### DESCRIPTION OF THE DRAWINGS

FIG. 1 is block diagram view of an LED system including a primary LED device, an auxiliary LED device, and a control unit according to an exemplary embodiment.

FIG. 2 is a cross-section view of an LED chip of the primary LED device of FIG. 1 before an etching process according to the exemplary embodiment.

FIG. 3 is a cross-section view of the LED chip of FIG. 2 chip after an etching process.

FIG. 4 is a cross-section view of an LED chip according to a first alternative exemplary embodiment.

FIG. 5 is a cross-section view of an LED chip according to a second alternative exemplary embodiment.

FIG. 6 is a flow diagram of an exemplary method of forming an LED chip according to an embodiment of the present invention.

FIG. 7 is a flow diagram of an exemplary method performed by the control unit of FIG. 1.

The drawings are only for purposes of illustrating preferred embodiments and are not to be construed as limiting the disclosure. Given the following enabling description of the drawings, the novel aspects of the present disclosure should become evident to a person of ordinary skill in the art. This detailed description uses numerical and letter designations to refer to features in the drawings. Like or similar designations in the drawings and description have been used to refer to like or similar parts of embodiments of the invention.

### DETAILED DESCRIPTION OF THE EMBODIMENTS

As required, detailed embodiments are disclosed herein. It must be understood that the disclosed embodiments are merely exemplary of various and alternative forms. As used herein, the word “exemplary” is used expansively to refer to embodiments that serve as illustrations, specimens, models, or patterns. The figures are not necessarily to scale and some features may be exaggerated or minimized to show details of particular components. In other instances, well-known components, systems, materials, or methods that are know to those having ordinary skill in the art have not been described in detail in order to avoid obscuring the present disclosure. Therefore, specific structural and functional details disclosed herein are not to be interpreted as limiting, but merely as a basis for the claims and as a representative basis for teaching one skilled in the art.

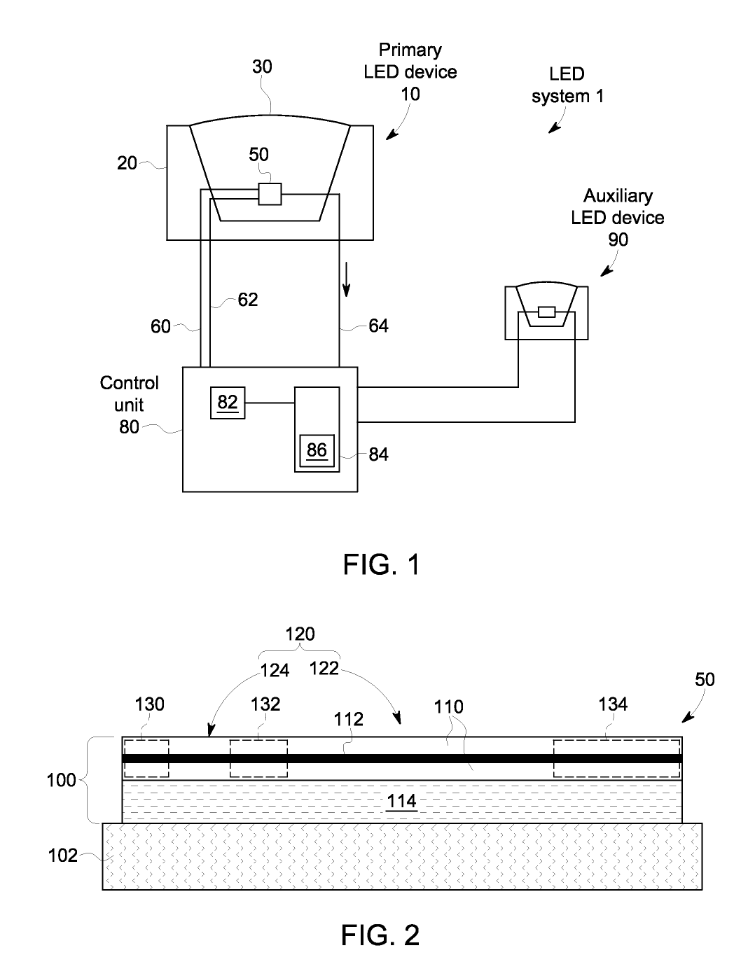

FIG. 1 is a block diagram view of an LED system 1 including a primary LED device 10, an auxiliary LED device 90, and a control unit 80. The auxiliary LED device 90 is similar to the primary LED device 10. The LED devices 10, 90 together are referred to herein as an LED array. In alternative embodiments, an LED array includes two or more LED devices.

The primary LED device 10 includes a case 20, a lens 30, and an LED chip 50. Leads 60, 62, 64 connect the LED chip 50 to the control unit 80. The control unit 80 includes a processor 82 and a tangible computer-readable medium or memory 84 that stores computer-executable instructions for performing methods described herein. The memory 84 includes a control application 86, discussed in additional detail below. The technical effect of the control application 86 is improved LED color control.

The term computer-readable media and variants thereof, as used in the specification and claims, refer to storage media. In some embodiments, storage media includes volatile and/or non-volatile, removable, and/or non-removable media, such as, for example, random access memory (RAM), read-only memory (ROM), electrically erasable programmable read-only memory (EEPROM), solid state memory or other memory technology, CD ROM, DVD, BLU-RAY, or other optical disk storage, magnetic tape, magnetic disk storage or other magnetic storage devices.

An LED chip is commonly referred to as an LED die or a semiconductor die. Various designs of an LED chip include lateral flip-chip architecture, lateral architecture, and vertical architecture. However, the teachings herein are applicable to other LED chip designs and LED device designs.

Generally, lateral architectures include an insulating substrate (e.g., sapphire or silicone carbide) located at a bottom of an LED chip. For lateral architectures, contacts are placed on a top surface of the LED chip (on a mesa structure described below), opposite the insulating substrate.

Generally, vertical architectures include a conducting substrate (e.g., copper or silicone) located at a bottom of an LED chip. For vertical architectures, contacts are placed on a bottom surface of the conducting substrate of the LED chip and on a top surface of a mesa of the LED chip.

For purposes of description, the terms “top” and “bottom” are used. However, it should be understood that the terms do not limit the orientation of the LED chips described herein. Rather, the terms are used to distinguish parts of the LED chips from one another.

FIG. 2 is a cross-section view of an LED chip 50 of the primary LED device 10, prior to etching, according to an exemplary embodiment. In FIG. 2, the LED chip 50 has a lateral flip-chip architecture and includes a heterostructure 100 formed on a substrate 102.

The heterostructure 100 includes layers of semiconducting material. By way of background, similar layers of semiconducting material are represented by a single layer and element number. Specifically, the layers of the heterostructure 100 are represented by layers 110, 112, 114. However, it should be understood that each layer 100, 112, 114 generally includes multiple layers.

The LED chip 50 includes a mesa structure 120 formed from the heterostructure 100 by an etching process described in further detail below. The mesa structure 120 includes an LED mesa portion 122 and a PD mesa portion 124.

In an exemplary embodiment, the semiconducting material of layers 110, 114 is gallium nitride (GaN) and the material of layer 112 is aluminum indium gallium nitride (AlInGaN). In alternative embodiments, including embodiments described in further detail below, exemplary semiconducting materials include aluminum gallium indium phosphide (AlGaInP), gallium phosphide (GaP), combinations thereof, and the like.

The layers 110, 114 of the semiconducting material are doped with impurities. Layer 110 is a p-type doped semiconductor layer and layer 114 is an n-type doped semiconductor layer. Hereinafter, layer 110 is referred to as p-type layer and layer 114 is referred to as n-type layer.

Active layer 112 is located between at least part of the n-type layer 114, and at least part of the p-type layer 110 (e.g., at or near the p-n junction). An active layer is also commonly referred to as a light-emitting layer.

In alternative embodiments, the heterostructure 100 includes additional layers. In such embodiments, p-type layer 110, active layer 112, and n-type layer 114 maintain the same relative position, although the layers may not be directly layered adjacent to one another.

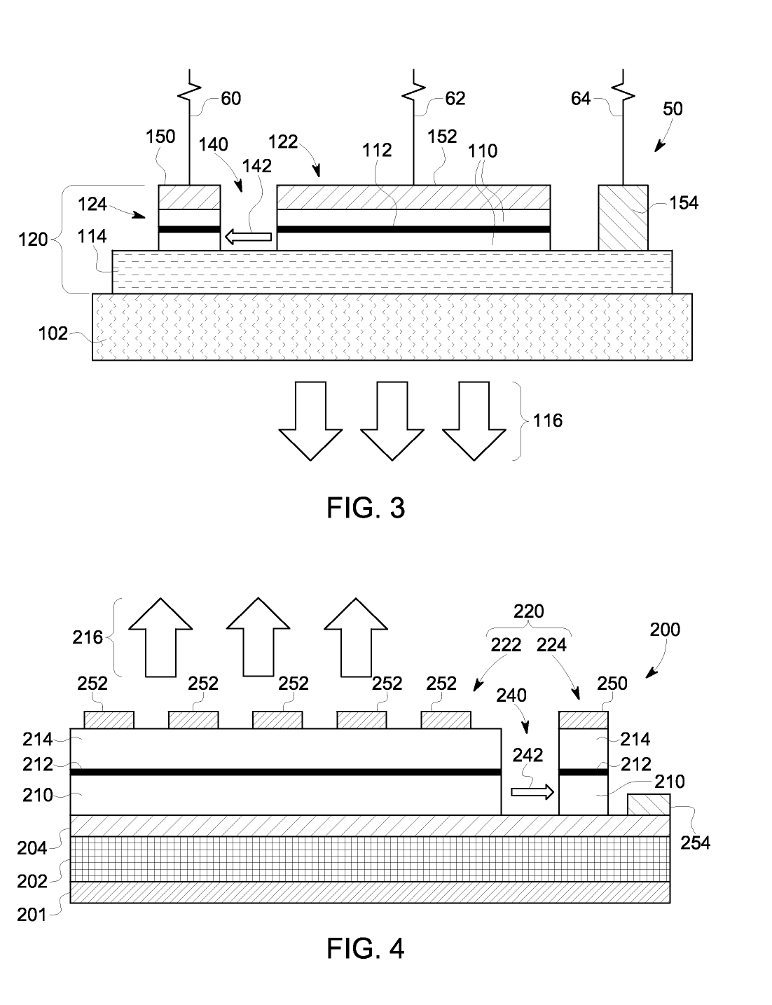

The layers 110, 114 are doped such that current flows from the p-type layer 110 (anode) to the n-type layer 114 (cathode) through the active layer 112. When an electron meets a hole in the active layer 112, optical energy is released and light (represented by arrows 116 in FIG. 3) is emitted. As used herein, the term optical energy is used although terms such as optical power, radiometric power, radiant energy, and the like are also commonly used.

FIG. 3 is a cross-section view of the LED chip 50 of FIG. 2 chip after an etching process. The etching process removes heterostructure portions 130, 132, 134 of the monolithic heterostructure 100. The heterostructure portions 130, 132, 134 that are removed from the monolithic heterostructure 100 by the etching process are shown in dashed lines in FIG. 2. FIG. 3 depicts the mesa structure 120 after the heterostructure portions 130, 132, 134 are removed from the heterostructure 100.

Removal of heterostructure portion 132 defines a channel 140, which is an air gap that separates the LED mesa portion 122 and the PD mesa portion 124 from one another. The channel 140 electrically isolates the active layer 112 of the LED mesa portion 122 from the active layer 112 of the PD mesa portion 124. Removal of heterostructure portion 134 exposes n-type layer 114, such a metal contact 154, discussed more fully below, can be positioned on the n-type layer 114.

The LED mesa portion 122 and the PD mesa portion 124 are formed as a unit from the heterostructure 100. Because the LED mesa portion 122 and the PD mesa portion 124 are both formed from the monolithic hetrostructure 100, the heterostructure of the LED mesa portion 122 is the same as the heterostructure of the PD mesa portion 124. Particularly, the energy gap of the active layer 112 of the PD mesa portion 124 is the same as the energy gap of the active layer 112 of the LED mesa portion 122.

In FIG. 3, the substrate 102 is a light-transmissive substrate such that light 116 is emitted through the substrate 102. For example, the substrate 102 may be, for e.g., sapphire, silicon carbide (SiC), or combinations thereof

Metal contacts 150, 152, 154 are positioned on the LED chip 50 including on the LED mesa portion 122 and the PD mesa portion 124. Specifically, PD anode contact 150 is located on top of the p-type layer 110 of the PD mesa portion 124, LED anode contact 152 is located on top of the p-type layer 110 of the LED mesa portion 122, and cathode contact 154 is located on top of the n-type layer 114 of the mesa structure 120.

In the exemplary embodiments, the PD anode contact 150 is a non-transparent metal contact (e.g., a pad or layer) that covers the top area of the PD mesa portion 124. The PD anode contact 150 blocks the PD mesa portion 124 from optical energy (not shown) emitted from neighboring LED devices (e.g., auxiliary LED device 90). The LED anode contact 152 is a reflective metal contact and the cathode contact 154 is a metal contact.

The metal contacts 150, 152, 154 can include metal stuck compositions. For example, metal stuck compositions for p-GaN include Palladium-Silver-Gold-Titanium-Gold (Pd—Ag—Au—Ti—Au) metal layers where Silver (Ag) functions as a reflector. As another example, metal stuck layers for n-GaN include Titanium-Aluminum (Ti—Al) metal layers.

The anode contacts 150, 152 are connected to the leads 60, 62 (shown in FIG. 1) and the cathode contact 154 is connected to the lead 64 (also shown in FIG. 1). The contacts can be connected by solder, wires, electrodes, or combinations thereof, and the like.

The primary LED device 10 is configured such that the mesa portion 122 functions as an LED and the PD mesa portion 122 functions as a photo diode sensor. A current through the lead 62 and the metal contact 152 flows through the LED mesa portion 122. The flow of the current through the LED mesa portion 122 emits optical energy, including the optical energy 142 that travels across the channel 140 to the PD mesa portion 124. The PD mesa portion 124 absorbs the optical energy 142 and generates a photocurrent.

Since the heterostructures of the LED mesa portion 122 and PD mesa portion 124 are the same, the spectra (spectral power) of the optical energy emitted from the LED portion 122 is substantially identical to spectra (spectral power) of the optical energy absorbed by the PD mesa portion 124. The PD mesa portion 124 has a responsivity or sensitivity to optical energy of wavelengths emitted by the LED mesa portion 122. The sensitivity of the PD mesa portion 122 is the ratio of optical energy (in watts) incident on the PD mesa portion 122 to the photocurrent output in amperes. It is usually expressed as the absolute responsivity in amps per watt although optical energy is usually expressed as watts/cm̂2 and that photocurrent as amps/cm̂2.

As such, when the active layer 112 of the PD mesa portion 124 absorbs part of the optical energy 142 emitted from active layer 112 of LED mesa portion 122, a photocurrent generated by the PD mesa portion 124 is substantially proportional to the emitted optical energy of the LED mesa portion 122.

In alternative embodiments, the energy gap of active layers 112 of the mesa portions 122, 124 may not be the same. For example, if the energy gap of the active layer 112 of the LED mesa portion 122 is greater than the energy gap of the active layer 112 of the PD mesa portion 124, a photocurrent generated by the PD mesa portion 124 will be higher than if the active layers 112 are the same. Mesa portions 122, 124 with different heterostructures, can be achieved by selective epitaxy. The control unit 80 is calibrated to compensate for the differences in active layers 112.

As noted earlier, the control unit 80 is configured to determine and provide a current through the LED mesa portion 122 of the primary LED device 10, determine and provide a current through the auxiliary LED device 90, and to receive, measure, and determine a current through (generated by) the PD mesa portion 124 of the primary LED device 10.

The control application 86, noted above, is configured to coordinate the current through at least one of the LED mesa portion 122 of the primary LED device 10 and the auxiliary LED device 90 as a function of the photocurrent through the PD mesa portion 124 of the primary LED device 10.

The control unit 80 is configured to supply a current to the LED mesa portion 122 through the lead 62. The current flows through the LED mesa portion 122 and causes the active layer 112 of the LED mesa portion 122 to emit optical energy 142. The control unit 80 also receives and measures the photocurrent through (generated by) the PD mesa portion 124 through the lead 60.

FIG. 4 is a cross-section view of an LED chip 200 according to an alternative exemplary embodiment of the present invention. Where the LED chip 200 includes features that are substantially similar to the features of LED chip 50 (see FIG. 2), similar element names and reference characters are used.

In FIG. 4, the LED chip 200 is configured to emit light 216 (illustrated as upward arrows) from the top of the LED chip 200. The LED chip 200 includes a metal stack 201 for soldering LED chip 200 to a device (e.g., device 10), a substrate 202 (e.g., silicon), a metal reflective contact 204 (e.g., to a p-type layer), a p-type layer 210 (e.g., GaP), an active layer 212, and an n-type layer 214 (e.g., AlInGaP).

The LED chip 200 includes a mesa structure 220 including an LED mesa portion 222 and a PD mesa portion 224 separated by a channel 240. The mesa portions 222, 224 have the same heterostructure including the layers 210, 212, 214.

In addition, the LED chip 200 includes contacts on the top of the LED chip 200. Specifically, a metal contact 250 (PD cathode) is on top of n-type layer 214 of PD mesa portion 224, a metal contact mesh 252 (LED cathode) is on top of n-type layer 214 of LED mesa portion 222, and a wire bonding pad 254 (common anode) is on top of the metal reflective contact 204.

Current flows through the LED mesa portion 222 and causes the active layer 212 of the LED mesa portion 222 to emit optical energy, including optical energy 242 that is absorbed by the PD mesa portion 224. The metal contact mesh 252 allows light 216 to be emitted from the top of the LED mesa portion 222.

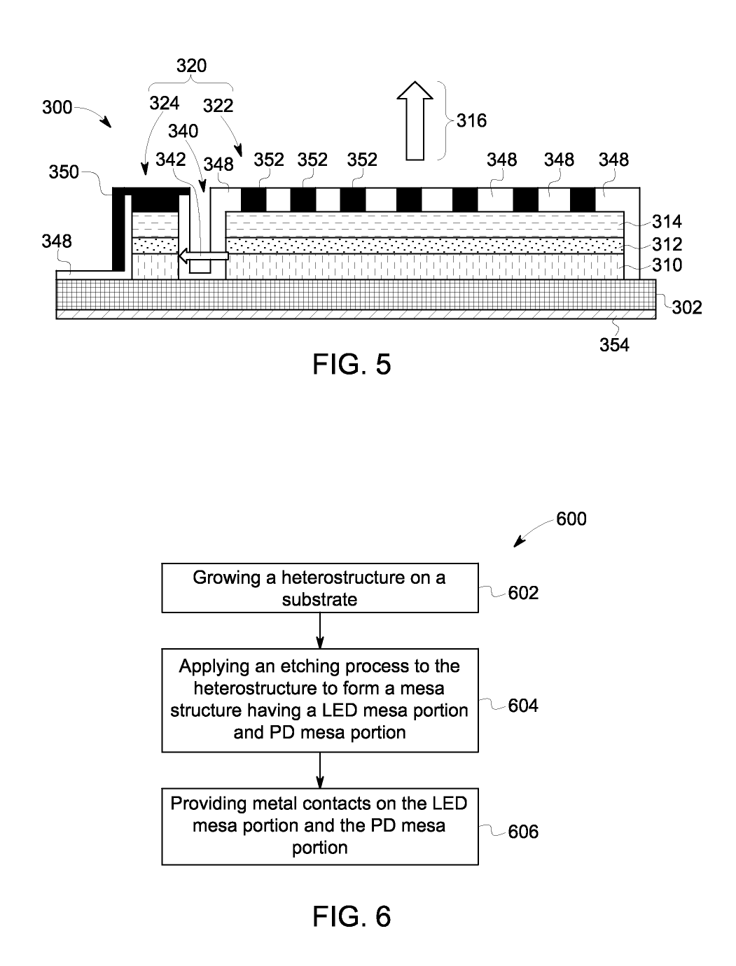

FIG. 5 is a cross-section view of an LED chip 300 according to a second alternative exemplary embodiment. Where the LED chip 300 includes features that are substantially similar to the features of the LED chip 50 (see FIG. 2), similar element names and reference characters are used.

In FIG. 5, the LED chip 300 is configured to emit light 316 (illustrated as the upward arrow) from the top of the LED chip 300. The LED chip 300 includes a substrate 302 (e.g. silicon), an n-type layer 314 (e.g., GaN or GaP), an active layer 312 (e.g, AlInGaN or AlInGaP), and a p-type layer 310 (e.g., GaN or GaP).

In alternative embodiments, the heterostructure includes additional layers. In such embodiments, p-type layers 310, active layer 312, and n-type layer 314 maintain the same relative position, although the layers may not be directly layered adjacent to one another.

The LED chip 300 includes a mesa structure 320 having an LED mesa portion 322 and a PD mesa portion 324, separated by a channel 340. The mesa portions 322, 324 have the same heterostructure, including layers 310, 312, 314. Current flows through the LED mesa portion 322 and causes the active layer 312 of the LED mesa portion 322 to emit optical energy, including optical energy 342 that is absorbed by the PD mesa portion 324.

The LED chip 300 includes contacts on the top and bottom of the LED chip 300. A dielectric layer 348 is grown on the top of the mesa structure 320 and metal contacts 350, 352 on the top of the LED chip 300 are created in the spaces of the dielectric layer 348.

Specifically, a metal contact 350 (PD cathode) is on the top of n-type layer 314 and on the outside (opposite the channel 340) of PD mesa portion 324, a metal contact mesh 352 (LED cathode) is on top of n-type layer 314 of LED mesa portion 322, and a metal contact 354 (common anode) is on the bottom of the substrate 302. The metal contact 350 provides additional isolation from optical power from auxiliary LED devices (e.g, auxiliary LED device 90).

A heterostructure can be formed on a substrate according to various processes such as metal organic chemical vapor deposition (MOCVD) epitaxy. FIG. 6 depicts an exemplary method of such a formation process.

FIG. 6 is a flow diagram of an exemplary method 600 of forming an LED chip according to an embodiment of the present invention. The method 600, based upon the illustrations of FIGS. 2 and 3, includes a heterostructure growth step 602. In the growth step 602, the heterostructure 100 is formed by epitaxial growth of the layers 110, 112, 114 on substrate 102. The n-type layer 114 is grown on the substrate 102, the p-type layer 110 is grown on the n-type layer 114, and the active layer 112 is grown in between layers of the p-type layer 110.

For example, some of the layers of the p-type layer 110 are grown on the n-type layer 114, then the active layer 112 is grown on layers of the p-type layer 110, and then additional layers of the p-type layer 110 are grown on the active layer 112. The resulting heterostructure 100 is monolithic, formed as a single piece.

The method 600 also includes an etching step 604. In the step 604, an etching process is applied to the monolithic heterostructure 100 to define the mesa structure 120. Exemplary etching processes include dry-etching techniques such as, ion reactive etching, wet-etching techniques, chemical etching, laser cutting techniques, mechanical etching (e.g., such as with a diamond enforced disk), combinations thereof, and the like.

In a contact application step 606, contacts 150, 152, 154 are positioned on the LED chip 50 and leads 60, 62, 64 are connected to the contacts 150, 152, 154. The contacts 150, 152, 154 are positioned such that current that is directed through the LED mesa portion 122 is isolated from current through (generated by) the PD mesa portion 124.

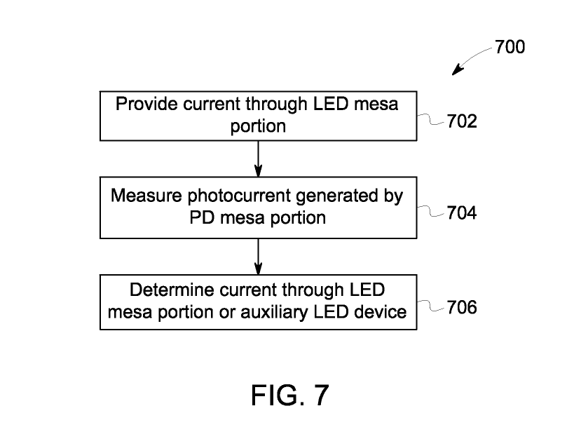

FIG. 7 is a flow diagram of an exemplary method 700 performed by the control unit 80 (see FIG. 1) according to computer executable instructions of the control application 86.

The method 700 includes an LED current step 702. In the step 702, the control unit 80 provides a current that flows through the lead 62 and the LED mesa portion 122. The flow of the current through the LED mesa portion 122 generates optical energy. Some of the optical energy (optical energy 142) travels across that channel 140 and is absorbed by the PD mesa portion 124. The PD mesa portion 124 generates a photocurrent that flows through the lead 60.

According to a PD current step 704, the control unit 80 measures or otherwise determines the photocurrent. Because photocurrent generated by the PD mesa portion 124 is substantially proportional to the optical energy emitted by the LED mesa portion 122, the photocurrent from the PD mesa portion 124 provides feedback, for example, regarding how much optical energy is generated by the current as it flows through the LED mesa portion 122. As such, the control unit 80 determines the optical energy output of the LED portion 122 as a function of the photocurrent generated by the photo diode portion 124.

According to an adjusted current step 706, the control unit 80 determines an adjusted input current as a function of the photocurrent. For example, if the photocurrent decreases when compared to a previous photocurrent measurement, the control unit 80 increases the current to the LED mesa portion 122 to maintain a substantially constant optical energy output from the LED mesa portion 122 (e.g., to compenstate for degradation of the LED mesa portion 122).

Degradation is a decrease in optical energy that is generated by the LED mesa portion 122 using the same input current. Since the photocurrent is proportional to optical energy, a drop in photocurrent generated by the PD mesa portion 124 represents a drop in optical energy generated by the LED mesa portion 122.

Alternatively or additionally, the control unit 80 can compensate for degradation of the optical energy output of the LED mesa portion 122 of primary LED device 10 by adjusting increasing the current through one or more auxiliary LED devices, such as auxiliary LED device 90, to maintain an overall constant level of optical energy from the LED array (here, LED devices 10, 90). Increasing the current through one or more auxiliary LED devices is advantageous if increasing the current to the LED mesa portion 122 of the primary LED device 10 would accelerate degradation of the LED mesa portion 122 of primary LED device 10.

While the methods described herein may, at times, be described in a general context of computer-executable instructions, the methods of the present disclosure can also be implemented in combination with other applications and/or as a combination of hardware and software. The term application, or variants thereof, is used expansively herein to include routines, program modules, programs, components, data structures, algorithms, and the like.

Applications can be implemented on various system configurations, including servers, network systems, single-processor or multiprocessor systems, minicomputers, mainframe computers, personal computers, hand-held computing devices, mobile devices, microprocessor-based, programmable consumer electronics, combinations thereof, and the like.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

1. A light emitting diode (LED) chip, comprising:
a substrate; and
a mesa structure formed from a heterostructure grown on the substrate, the mesa structure including:
an LED mesa portion; and
a photo diode (PD) mesa portion, wherein a channel separates the LED mesa portion from the PD mesa portion.

2. The LED chip of claim 1, wherein the heterostructure includes an n-type layer, a p-type layer; and
an active layer between at least part of the n-type layer and at least part of the p-type layer.

3. The LED chip of claim 2, wherein a channel separates the active layer of the LED mesa portion from the active layer of the PD mesa portion.

4. The LED chip of claim 1, comprising a first metal contact on the LED mesa portion and a second metal contact on the PD mesa portion.

5. The LED chip of claim 4, wherein the second metal contact is a non-transparent metal contact.

6. The LED chip of claim 4, comprising a third metal contact on the LED chip.

7. The LED chip of claim 6, wherein the first metal contact and the second metal contact are anodes, and the third metal contact is a common cathode.

8. The LED chip of claim 6, wherein the first metal contact and the second metal contact are cathodes and the third metal contact is a common anode.

9. The LED chip of claim 1, wherein the LED mesa portion is configured to emit optical energy to the PD mesa portion through the channel.

10. The LED chip of claim 9, wherein the PD mesa portion is configured to absorb optical energy from the LED mesa portion and generate a photocurrent.

11. The LED chip of claim 1, wherein the PD mesa portion includes a metal contact,
wherein the metal contact covers a top and an outside surface of the PD mesa portion.

12. A light emitting diode (LED) system, comprising:
a first LED device, including:
an LED chip, including:
a substrate; and
a mesa structure formed from a heterostructure grown on the substrate, the mesa structure including:
an LED mesa portion; and
a photo diode (PD) mesa portion, wherein a channel separates the LED mesa portion from the PD mesa portion; and
a control unit configured to (a) provide a first current through the LED mesa portion, and (b) measure a photocurrent generated by the PD mesa portion.

13. The LED system of claim 12, wherein the photocurrent generated by the PD mesa portion is substantially proportional to optical energy emitted by the first LED mesa portion as first current passes through the LED mesa portion.

14. The LED system of claim 13, wherein the control unit is configured to determine the first current through the LED mesa portion as a function of the photocurrent generated by the PD mesa portion.

15. The LED system of claim 13, further comprising:
at least one auxiliary LED device,
wherein the control unit is configured to provide a second current through the auxiliary LED device as a function of the photocurrent generated by the PD mesa portion of the first LED device.

16. A method of forming a light emitting diode (LED) chip, comprising:
growing a heterostructure on a substrate; and
applying an etching process to the heterostructure to form a mesa structure including an LED mesa portion and a photo diode (PD) mesa portion;
wherein applying an etching process comprises forming a channel that separates the LED mesa portion from the PD mesa portion.

17. The method of claim 16, the growing a heterostructure comprising growing an n-type layer, a p-type layer, and an active layer.

18. The method of claim 17, wherein applying an etching process comprises forming the channel to separate the active layer of the LED mesa portion from the active layer of the PD mesa portion.

19. The method of claim 18, further comprising providing a metal contact on the PD mesa portion, wherein the metal contact covers a top and an outside surface of the PD mesa portion.

20. The method of claim 16, further comprising providing a first metal contact on the LED mesa portion, a second metal contact on the PD mesa portion, and a third metal contact on the LED chip.
